(19) United States
(12) Patent Application Publication
(10) Pub. No.: US 2026/0231819 A1
(43) Pub. Date: Aug. 6, 2026

(54) MICROELECTRONICS DEVICE PACKAGE WITH ISOLATION AND MICRO-TRANSFORMER

(71) Applicant: Texas Instruments Incorporated, Dallas, TX (US)

(72) Inventors: Suvadip Banerjee, Bangalore (IN); Yi Yan, San Jose, CA (US); Dongbin Hou, Plano, TX (US); Michael Lueders, Freising (DE); Giacomo Calabrese, Freising (DE)

(21) Appl. No.: 19/043,330

(22) Filed: Jan. 31, 2025

(51) Int. Cl. H01L 25/18; H01L 23/00; H01L 23/31; H01L 23/495; H01L 25/00; H10D 1/20

(52) U.S. Cl. CPC H10W 90/00; H10D 1/20; H10W 90/811; H10W 72/552; H10W 72/5522; H10W 72/5524; H10W 72/5525; H10W 72/555; H10W 74/111; H10W 90/756; H10W 90/759

(57) ABSTRACT

An apparatus includes: a package substrate having a first set of leads spaced from a first die pad, and a second set of leads spaced from a second die pad, a space between the first and the second die pad forming an electrical isolation barrier; a bobbin mounted on the second die pad; a first coil around a first portion of the bobbin and coupled to a first semiconductor die on the first die pad, and a second coil around a second portion of the bobbin coupled to a second semiconductor die on the second die pad, the first coil, the second coil and the bobbin forming a micro-transformer; and mold compound covering the first die pad, the second die pad, the micro-transformer, portions of the first set of leads, and portions of the second set of leads, the mold compound forming a body of a microelectronic device package.

### TECHNICAL FIELD

This disclosure relates generally to microelectronic device packages, and more particularly to microelectronic device packages including semiconductor dies and transformers mounted in a package with isolation.

### BACKGROUND

Processes for producing microelectronic device packages include mounting one or more semiconductor dies to a package substrate and subsequently covering the electronic devices with a dielectric material, such as a mold compound, to form packaged microelectronic devices.

Incorporating passive components such as capacitors, inductors, and coils with semiconductor devices in a microelectronic device package is increasingly done. These microelectronic device packages can be referred to as “multichip modules” or as “system-in-package” or “SIP” devices. Power package applications include packaging multiple devices together in a system using passive components such as resistors, capacitors, inductors, and coils with semiconductor dies to increase integration, increase performance and reduce system board area. Integrating the devices together into a package make the microelectronic device package with the passives needed for a common function act as a single component. Increasing integration by packaging passive components and the associated semiconductor device dies together in a single microelectronic device package increases ease of use and reduces board design time. Sometimes a passive component is mounted next to or mounted on or over a completely packaged semiconductor device.

In certain applications, electrical isolation is required between terminals of a microelectronic device package. Some terminals of the microelectronic device package are configured for connection to a first voltage domain, while other terminals of the microelectronic device package are configured for connection to a second voltage domain, the first and second voltage domains having isolated grounds. An example application for a microelectronics device package with electrical isolation is a DC-DC converter for a power supply. A DC-DC converter can be arranged to deliver power from a voltage supply in a first voltage domain to a load coupled to an isolated ground of a second voltage domain. Because the two voltage domains are isolated one from the other, high voltage potentials of tens, hundreds or thousands of volts can occur between terminals coupled to the two different voltage domains. To safely transfer current from one voltage domain to the other, for example in the DC-DC converter application, electrical isolation between devices coupled to one domain and devices coupled to the other voltage domain is required. In example DC-DC applications, a transformer can be used. In an application where lower power signals such as communication signals are to be transferred across the isolation barrier between voltage domains, a capacitive coupling semiconductor signal isolation device can be used to transfer lower energy or analog or digital signals across an electrical isolation barrier formed within the microelectronics device package. In some applications, a power field effect transistor (FET) can be used as a switch to control current flowing through a primary coil, while current generated in a corresponding secondary coil can be used by a receiving semiconductor device to create an isolated output voltage for powering a load. In a particular example, a system can be implemented using a microelectronic device package with reinforced electrical isolation to provide the necessary power control functions and including a primary side switch, while a transformer can be provided internal to the microelectronic device package to enable implementing an AC-DC adapter, to implement a DC-DC converter as described above, a battery charger, or another power supply function.

Forming transformers for isolated power devices can require expensive laminate substrate structures. In an example, a substrate is manufactured having coils formed within it that are spaced from one another in dielectric material. While a useful transformer suitable for use in a microelectronic device package can be formed in a laminate substrate, the laminate transformer comes with substantial cost (compared to the other components in the package), so that the transformer substrate can form a substantial portion of the overall cost of the product.

A continuing need thus exists for a robust and economical transformer that can be integrated into microelectronic device packages with electrical isolation, and which can be used in isolated packages for power applications and can also be used in isolated signaling applications.

### SUMMARY

In a described example, an apparatus includes: a package substrate having a device side surface and including a first set of leads spaced from a first die pad configured for mounting semiconductor dies, and having a second set of leads spaced from a second die pad configured for mounting additional semiconductor dies, the first die spaced from the second die pad, a space between the first die pad and the second die pad forming an electrical isolation barrier; at least one semiconductor die mounted to the device side surface of the first die pad and at least one semiconductor die mounted to the device side surface of the second die pad; a bobbin mounted on the device side surface of the second die pad, the bobbin extending away from the device side surface of the second die pad; a first coil around a first portion of the bobbin and coupled to a first semiconductor die on the first die pad, and a second coil around a second portion of the bobbin coupled to a second semiconductor die on the second die pad, the first coil and the second coil spaced from one another, the first coil, the second coil and the bobbin forming a micro-transformer; electrical connections formed between bond pads of at least one semiconductor die on the first die pad and the first set of leads, and formed between bond pads of the at least one semiconductor die on the second die pad and the second set of leads; and mold compound covering the first die pad, the second die pad, the electrical connections, the micro-transformer, portions of the first set of leads, and portions of the second set of leads, the mold compound forming a body of a microelectronic device package.

A microelectronic device package, including: a package substrate having a device side surface and an opposite side surface and including a first set of leads spaced from a first die pad configured for mounting semiconductor dies, and having a second set of leads spaced from a second die pad configured for mounting additional semiconductor dies, the first die pad and the first set of leads spaced from the second die pad and the second set of leads forming an electrical isolation barrier; at least one semiconductor die mounted to the device side surface of the first die pad and at least one semiconductor die mounted to the device side surface of the second die pad; a bobbin mounted on the device side surface of the second die pad, the bobbin extending away from the device side surface of the second die pad; a first coil of insulated bond wire wrapped around a first groove in a first portion of the bobbin and coupled to a first semiconductor die on the first die pad, and a second coil of the insulated bond wire wrapped around a second groove in a second portion of the bobbin coupled to a second semiconductor die on the second die pad, the first coil and the second coil spaced from one another, the first coil, the second coil and the bobbin forming a micro-transformer; wire bonds between bond pads of the at least one semiconductor die on the first die pad and the first set of leads, and between bond pads of the at least one semiconductor die on the second die pad and the second set of leads; and mold compound covering the first die pad, the second die pad, the electrical connections, the micro-transformer, portions of the first set of leads, and portions of the second set of leads.

In another described example, a method includes: mounting semiconductor dies on a device side surface of a package substrate on a first die pad and on the device side surface of a second die pad of the package substrate, the package substrate further including a first set of leads spaced from the first die pad, a second set of leads spaced from the first set of leads and the first die pad, and the second die pad spaced from the second set of leads and spaced from the first die pad and the first set of leads, the first set of leads electrically isolated from the second set of leads; mounting a bobbin on the device side surface of the second die pad, the bobbin extending away from the device side surface of the second die pad; forming a first coil around a first portion of the bobbin that is coupled to a first semiconductor die on the first die pad, and forming a second coil around a second portion of the bobbin that is coupled to a second semiconductor die on the second die pad, the first coil and the second coil spaced from one another, the first coil, the second coil and the bobbin forming a micro-transformer; forming electrical connections between bond pads on the semiconductor dies and the first set of leads and the second set of leads; and covering the semiconductor dies, the electrical connections, the first die pad and the second die pad, and the micro-transformer with mold compound, and covering a portion of the first set of leads and a portion of the second set of leads with the mold compound, the mold compound forming a body of a microelectronic device package.

### BRIEF DESCRIPTION OF THE DRAWINGS

FIGS. 1A-1B illustrate, in a projection view and a close-up projection view, respectively, semiconductor dies on a semiconductor wafer and an individual semiconductor die.

FIGS. 2A-2C illustrate, in a top side projection view, a rear side projection view, and a cross-sectional view, respectively, a microelectronic device package of an example arrangement. FIGS. 2D, 2DD and 2E illustrate, in two side views and an end view, details of an example bobbin, and an example micro-transformer formed using the bobbin, suitable for use in the arrangements.

FIGS. 3A-3E illustrate, in a series of plan views from a device side, steps for mounting devices on a package substrate to form an example arrangement.

FIG. 4 illustrates, in an additional cross-sectional view, a microelectronic device package of an alternative arrangement.

FIG. 5 illustrates, in a further cross-sectional view, an additional microelectronic device package of another alternative arrangement.

FIG. 6 illustrates, in a flow diagram, selected steps of a method for forming the arrangements.

### DETAILED DESCRIPTION

Corresponding numerals and symbols in the different figures generally refer to corresponding parts, unless otherwise indicated. The figures are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor device” is used herein. A semiconductor device can be a discrete semiconductor device such as a bipolar transistor, a few discrete devices such as a pair of power FET switches fabricated together on a single semiconductor die, or a semiconductor device can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device. When semiconductor devices are fabricated on a semiconductor wafer and then individually separated from the semiconductor wafer, the individual units are referred to as “semiconductor dies.” A semiconductor die is also a semiconductor device.

The term “passive component” is used herein. As used herein, a passive component is a component without active devices, for example, a resistor, capacitor, inductor, coil, diode, or sensor. Examples useful in the arrangements include capacitors, resistors, coils, inductors, or transformers. In an illustrated example, a micro-transformer is formed using bobbin having a cylindrical body configured for wire wrapping to form coils using wire bonding tools. The coils are spaced from one another so that one coil can be configured as a primary and the other coil can be configured as a secondary in the transformer. The primary coil can be coupled to a first voltage domain, and the secondary coil to second voltage domain. In an example operation, current for power applications, or alternatively, isolated signals, can be transmitted across an isolation barrier using the primary coil to induce a corresponding current in the secondary coil.

The terms “electrical isolation,” “isolation,” “reinforced isolation” and “robust isolation” are used herein. In the example arrangements, a first set of leads and a second set of leads extend from the body of a device package. The first set of leads is configured for coupling to a first voltage domain. The second set of leads is configured for coupling to a second voltage domain. The first voltage domain and the second voltage domain have different and unrelated grounds that are physically and electrically isolated from one another. In operation, the first set of leads and the second set of leads may therefore be at greatly different potentials; a voltage difference between the first set of leads and the second set of leads can be tens, hundreds, or thousands of volts. To ensure the devices operate properly and to prevent damage to the devices within the device package, electrical isolation is required within the package. The term “isolation” means that, up to a maximum voltage that can be tens, hundreds, or thousands of volts, the two voltage domains are not unintentionally coupled due to dielectric breakdown in materials. The isolation is accomplished by a physical space within the microelectronic device package between the first set of leads and the second set of leads that is sufficiently large to prevent arcing or unwanted capacitive coupling between the first set of leads and the second set of leads. This can be referred to as an “isolation barrier.” Because the device package is a molded package, the space can be filled with mold compound. The terms “isolation”, “electrical isolation”, “robust isolation” and “reinforced isolation” as used herein mean that the microelectronic device package includes a spatial distance between the leads coupled to the first voltage domain and to the second voltage domain, and that the materials and leads are arranged to provide isolation between the first set of leads (and devices coupled to the first set of leads) and the second set of leads (and devices coupled to the second set of leads.) Signals or current can be intentionally transferred across the isolation barrier, for example using a micro-transformer to transmit power or signals across the isolation barrier without electrical coupling.

The term “microelectronic device package” is used herein. As used herein, a microelectronic device package has at least one semiconductor die electrically coupled to terminals and has a package body that protects and covers the at least one semiconductor die. The microelectronic device package can include additional semiconductor dies or additional elements. For example, in example arrangements multiple semiconductor die components are included. In example arrangements, multiple semiconductor dies can be packaged together using an isolation package substrate. The semiconductor die or dies is/are mounted to die pads on the isolation package substrate that are isolated from one another and spaced apart. An isolation device that uses an integral micro-transformer can be used to couple power or data signals between isolated semiconductor dies across the isolation barrier within the microelectronic device package.

The term “package substrate” is used herein. A package substrate is a substrate arranged to receive a semiconductor die and in the illustrated examples, other components, and to support the semiconductor die in a completed semiconductor device package. Package substrates useful with the arrangements include conductive leadframes, molded interconnect substrates (MIS), partially etched leadframes, pre-molded leadframes (PMLFs), embedded trace substrates (ETS), and multilayer package substrates. In an example arrangement, an isolation package substrate includes a conductive leadframe with multiple die pads, the die pads are spaced apart and are electrically isolated from one another. Leads of the isolation package substrate are configured to be coupled to a first voltage domain and to a second voltage domain, and the leads that are associated with the first voltage domain are isolated from the leads that are associated with the second voltage domain.

The term “shrink small outline package” or “SSOP” is used herein. A shrink small outline package is a microelectronic device package that has a reduced size when compared to a “small outline package” or “SOP.” A shrink small outline package has leads that extend from a mold compound package body to form terminals, the SSOP package has a lead-to-lead pitch of less than 1 millimeter. In an example arrangement, an SSOP microelectronic device package has a package length of about 10.3 millimeters, with a package body width of about 7.5 millimeters, and a thickness of about 2.28 millimeters, a size less than an SOP or than a small outline integrated circuit (SOIC) package used in prior approaches formed without use of the arrangements. An example SOP package, a small outline package, can have a body length of about 5.6-15.3 millimeters, depending on the number of terminals (sometimes referred to as “pin count”), a body width of about 5-6 millimeters, and a thickness of about 2-3 millimeters. Use of the arrangements allows a micro-transformer to be integrated into a microelectronic device package with a standard package form such as an SOP package or SSOP package, which reduces the cost of production and assembly using the packages of the arrangements, as standard or existing board designs and standard packaged device handling equipment (such as pick and place equipment) can be used with the arrangements.

In packaging microelectronic and semiconductor devices, mold compound may be used to partially cover a package substrate, to entirely cover the package substrate, to cover passive components, to cover semiconductor dies, and to cover the electrical connections made to the package substrate. This molding process can be referred to as an “encapsulation” process, although portions of the package substrates are often not covered in the mold compound during encapsulation; for example, terminals can be formed by portions of conductive leads that are exposed from the mold compound. The terminals are configured for electrical connections to the microelectronic device package. Encapsulation is often a compressive transfer molding process, where a thermoset mold compound such as an epoxy resin can be used. A room temperature solid or powdered epoxy resin mold compound can be heated to a liquid state, and then molding can be performed by pressing the liquid mold compound into a mold through runners or channels. Transfer molding can be used. Unit molds shaped to surround an individual device may be used, or a block molding process may be used, to form multiple packages simultaneously for several devices from mold compound. The devices to be molded can be provided in an array or matrix of several, hundreds or even thousands of devices in rows and columns on a package substrate strip or grid, the devices are then molded contemporaneously.

After the molding process is complete, the individual microelectronic device packages are cut apart from each other in a sawing operation. A mechanical saw is used to cut through the mold compound and any remaining package substrate material in saw streets formed between the devices. Portions of the package substrate leads are exposed from the mold compound package to form terminals for the microelectronic device packages. A trim and form tool can be used to separate temporary supports, or “tie bars” from the leads, and to form the leads into the desired shape, such as a gull-wing shape, for surface mounting to a board.

The term “scribe lane” is used herein. A scribe lane is a portion of semiconductor wafer between semiconductor dies. Sometimes in related literature the term “scribe street” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area between molded electronic devices used to allow a saw, such as a mechanical blade, laser, or other cutting tool to pass between the molded electronic devices to separate the devices from one another. This process is another form of singulation. When the molded electronic devices are provided in a strip with one device adjacent to another device along the strip, the saw streets are parallel and normal to the length of the strip. When the molded electronic devices are provided in an array of devices in rows and columns, the saw streets include two groups of parallel saw streets, the two groups are normal to each other, and the saw will traverse the molded electronic devices in two different directions to cut apart the packaged electronic devices from one another in the array.

The terms “micro-transformer” and “bobbin” are used herein. A micro-transformer is a transformer that is sized to be integrated within a microelectronic device package. A bobbin is a body used to form a transformer, including a micro-transformer as used herein. In an example arrangement, a micro-transformer is formed of a bobbin that can be a hollow cylinder of dielectric material with coils of conductive wire wrapped around the bobbin. The dimensions of the micro-transformer are compatible with integrated circuit packages in standard forms. An example micro-transformer has a height of about 1 millimeter above a package substrate, and a similar diameter. In an example arrangement, grooves or trenches are formed extending inwards from an outer surface of the bobbin and are configured to receive wire wrapped coils. The micro-transformer is formed during the packaging processes. Using wire bonding equipment, insulated bond wire is wrapped around a first portion of the cylinder of the bobbin to form a first coil and wrapped around a second portion of the cylinder of the bobbin to form a second coil, the two coils are spaced apart, the first coil, the second coil and the bobbin form a micro-transformer.

When in operation, the two coils are arranged to couple magnetically to one another. In some example arrangements, a ferrite core can be placed in a hollow cylinder in a central portion of the bobbin to increase the inductance. In other arrangements, a hollow cylinder can be used without the ferrite core to form the bobbin. The micro-transformer can be coupled to a first semiconductor die on a first die pad by wire bonding the ends of the first coil to bond pads on the first die, and can be coupled to a second semiconductor die on a second die pad by wire bonding the ends of the second coil to bond pads on the second die. The first die pad is spaced from the second die pad by an isolation barrier in the microelectronic device package. In this manner, energy from a first voltage domain can be transferred to the second voltage domain while the two voltage domains remain electrically isolated.

In an example arrangement, multiple components are mounted to die pads, either to a first die pad or to another second die pad spaced from and isolated from the first die pad, and semiconductor dies are mounted with bond pads on the semiconductor dies facing away from the die pads. Wire bonding processes using bond wire form wire bond connections between the bond pads and conductive portions of the leads.

Use of the micro-transformer, and the methods for assembly, reduces costs of the microelectronic device package substantially when compared to the use of a laminate substrate transformer, which is a much more costly prior approach. By using existing wire bonding equipment to form the coils of the micro-transformer, the assembly of the micro-transformer is done contemporaneously with existing packaging processes, along with making the wire bond connections between the semiconductor dies and the leads of the leadframe. Use of existing processes and equipment presently used in packaging semiconductor dies to implement the arrangements reduces the costs of adopting the micro-transformers of the arrangements and reduces costs of production of unit devices (when compared to the use of laminate transformer substrates or other types of transformers used in microelectronic device packages.

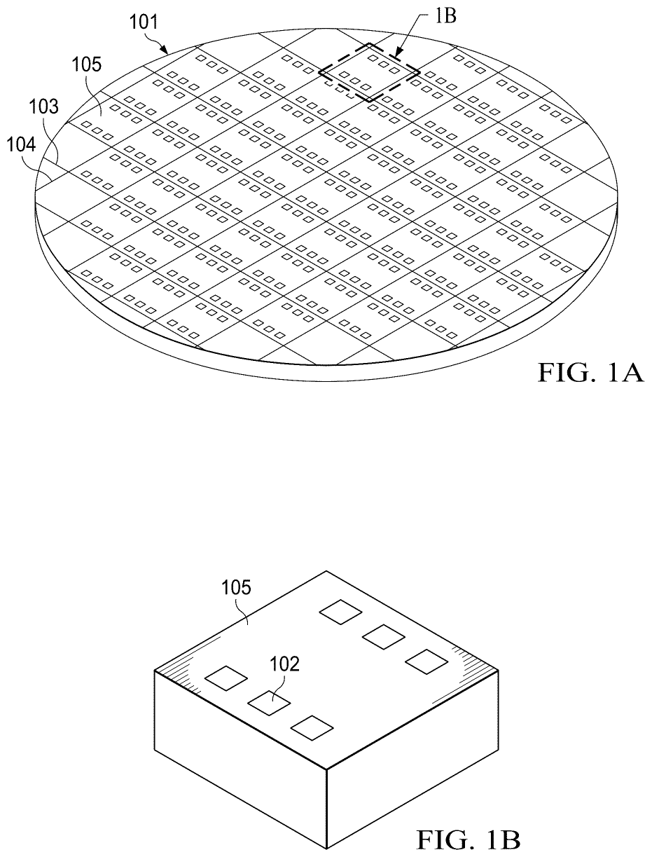

FIGS. 1A and 1B illustrate, in two projection views, a semiconductor wafer having semiconductor die devices formed on it that are configured for wire bonding, and an individual semiconductor die from the wafer configured for wire bonding and face-up mounting, respectively. In FIG. 1A, semiconductor wafer 101 is shown with an array of semiconductor dies 105 formed in rows and columns on a surface. The semiconductor dies 105 can be formed using processes in a semiconductor manufacturing facility, including ion implantation, doping, anneals, oxidation, dielectric and metal deposition, photolithography, pattern, etch, chemical mechanical polishing (CMP), electroplating, and other processes for making semiconductor devices. Scribe lanes 103 and 104, which are perpendicular to one another, and which run in parallel groups across the semiconductor wafer 101, separate the rows and columns of the completed semiconductor dies 105, and provide areas for dicing the wafer 101 to separate the semiconductor dies 105 from one another.

FIG. 1B illustrates a single semiconductor die 105 taken from semiconductor wafer 101. Semiconductor die 105 includes bond pads 102, which are conductive pads that are electrically coupled to devices (not shown) formed in the semiconductor die 105. Not shown for clarity of illustration are under-bump metallization (UBM) portions which can be formed over the bond pads 102 to improve plating and adhesion between the bond pads and ball bonds of bond wire (not shown for clarity of illustration) to be formed on the bond pads 102 in processes described later herein.

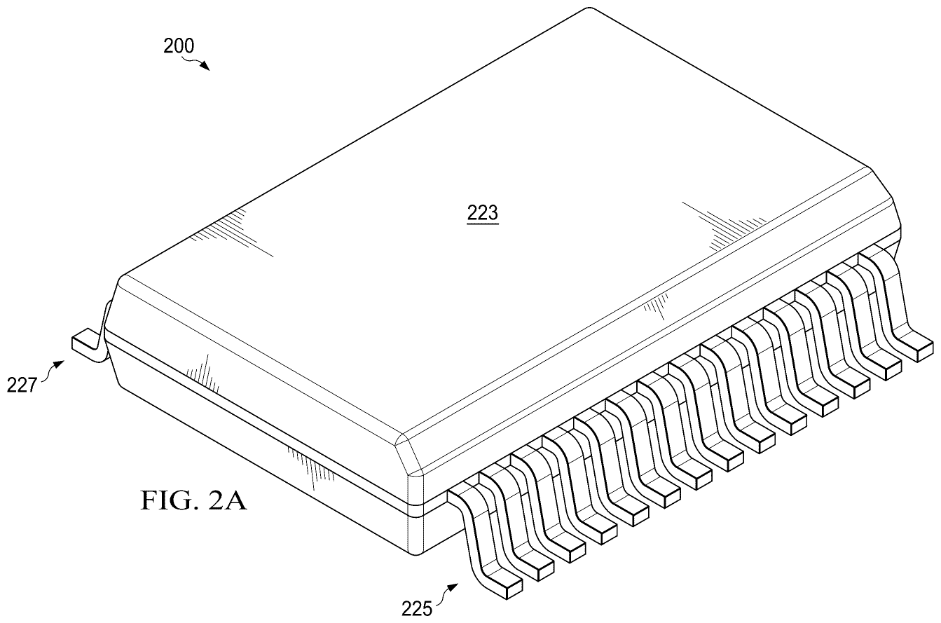

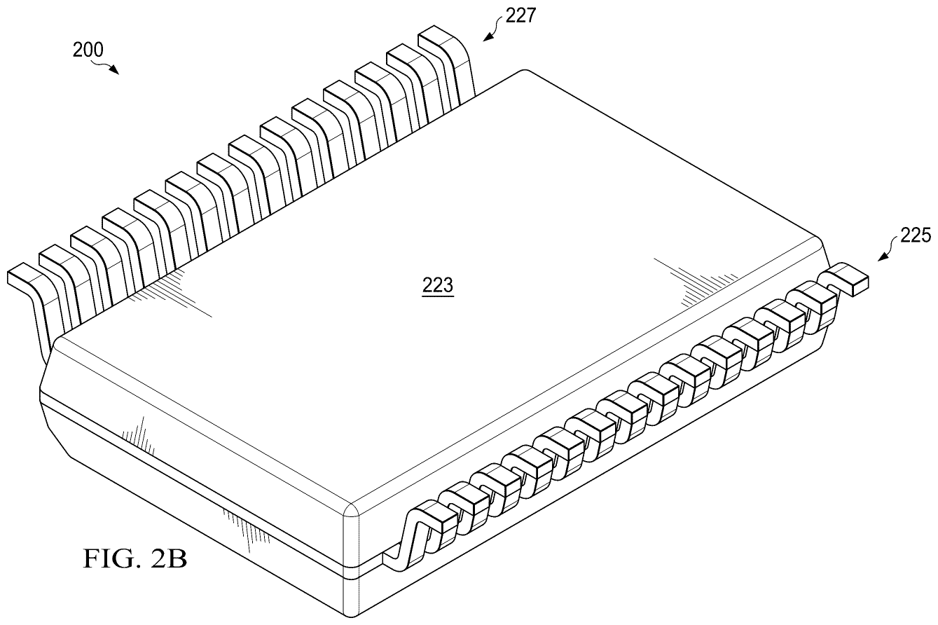

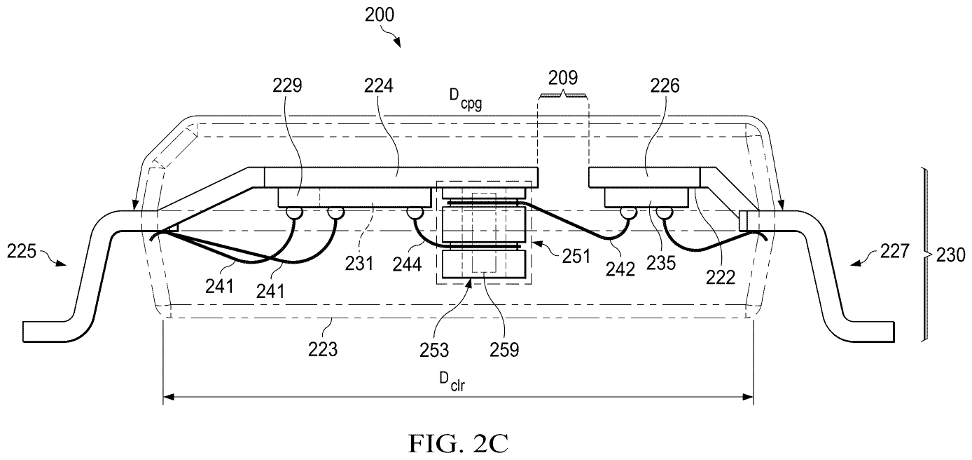

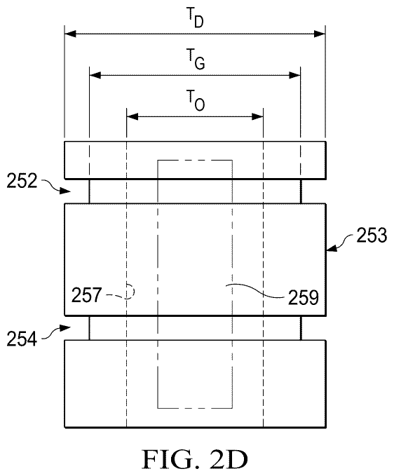

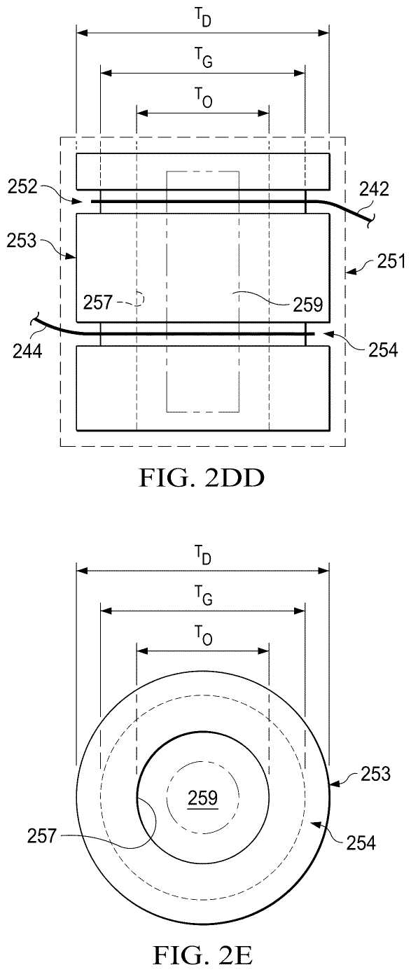

FIGS. 2A-2B illustrate, in a projection view and a cross-sectional view, respectively, a microelectronic device package 200 that can be used with an arrangement. In FIG. 2A, a microelectronic device package 200 is shown in a projection view from a top side surface. In the illustrated example, the microelectronic device package 200 is a shrink small outline package (SSOP), which is smaller than a small outline integrated circuit (SOIC) package or small outline package (SOP), in additional example arrangements any of these packages or other standard or custom packages can be used. The body of the microelectronic device package 200 is formed by mold compound 223. The first set of leads 225 and a second set of leads 227 are shown extending from a middle portion of the body of the package formed by mold compound 223. In the illustrated example the leads are shaped in a “gull wing” shape for use in surface mounting to a system board, for example using processes for surface mounting technology (“SMT.”) Leads 225 are arranged to be coupled to a first voltage domain, and leads 227 (more visible in FIG. 2B, as these leads are partially obscured in FIG. 2A) are configured to be coupled to a second voltage domain that is isolated from the first voltage domain.

In FIG. 2B, a projection view taken from the bottom or board side surface of the microelectronic device package 200 is shown. Leads 225 and 227 are shown on opposite sides of the body formed by mold compound 223. In an example the first set of conductive leads 225 is arranged to be coupled to a first voltage domain, while the second set of conductive leads 227 is arranged to be coupled to a second voltage domain that is isolated from the first voltage domain. The leads 225 and 227 extend away from the package body formed by mold compound 223 and are gull-wing shaped to form terminals with “feet” at the outward ends for use in surface mounting. Other lead shapes can be used. An advantage of “gull-wing” shaped leads is that these leads allow for some slight movement, for example due to movement of a board or of a device during package mounting, or due to thermal expansion of components while in operation, the slight movement of the leads can occur without causing a solder joint failure, thereby increasing board level reliability (“BLR.”)

FIG. 2C illustrates, in a cross-sectional view, the microelectronic device package 200 of FIGS. 2A-2B. Package substrate 230, in this example a conductive leadframe in an “upset” shape, with devices mounted on a device side surface facing the board side of the microelectronic device package 200, includes the first set of leads 225 and the second set of leads 227 that extend from the body of the microelectronic device package 200 formed by mold compound 223. Semiconductor dies or passive components 229, 231 and 235 are shown mounted on a device side surface 222 of the package substrate 230 and facing the board side of the microelectronic device package 200. The package substrate 230 has a split die pad design for providing electrical isolation, with components 229 and 231 shown mounted on a first die pad 224, and the semiconductor die 235 shown mounted on a second die pad 226. The space and materials between the leadframe die pad elements form an isolation barrier, numbered 209 in FIG. 2C. In alternative arrangements, additional semiconductor dies, passive components, or sensors can be mounted on either the first or second die pad to increase the integration of the microelectronic device package 200.

In FIG. 2C, two distances are shown, a clearance distance labeled “Dclr”, and a creepage distance labeled “Dcpg.” In microelectronic device packages such as the illustrated example 200 that provide electrical isolation between certain leads, and which provide isolation between the components arranged to be coupled to different voltage domains with isolated grounds, these distances must be greater than a minimum spacing in order to prevent arcs forming between conductive leads at different potentials (a clearance distance) and to prevent a leakage path from forming as a body effect current between leads of the different domains over the insulator material (a creepage distance over the body of the microelectronic device package).

In FIG. 2C, a micro-transformer 251 is shown mounted on die pad 224 and positioned near the isolation barrier 209. A bobbin 253 forms the body for the micro-transformer 251. A first coil is formed by a wire 242 that has bonds on two ends (note in the cross-sectional view, only one end of wire 242 is visible) of wire 242 that wraps around a first portion of the bobbin 253. A second coil is formed by wire 244, that has two ends (in the cross-sectional view only one end is visible) and that wraps around a second portion of the bobbin 253 at a position spaced from the first coil, the first coil is spaced from the second coil. An optional core 259 is shown positioned in a central opening in bobbin 253 of micro-transformer 251. The optional core 259 increases the inductance but can be omitted depending on the application.

Use of micro-transformer 251 provides the ability to integrate a transformer into the microelectronic device package 200 without the need for a laminated substrate transformer of a prior approach. The bobbin 253 of micro-transformer 251 can be formed of a material that is compatible with 3D printing and 3D or additive manufacturing, such as polylactic acid (“PLA”), acetonitrile butadiene styrene (“ABS”), acrylonitrile styrene acrylate (“ASA”), nylon, or polypropylene. The optional core 259 can be a ferrite material such as a magnetic mold compound, which can include metallic particles in an epoxy-resin carrier.

FIGS. 2D, 2DD, and 2E illustrate, in two side views and an end view, respectively, bobbin 253, and micro-transformer 251, in more detail. The illustrated example bobbin 253 has a cylindrical shape that can be used in the arrangements. The bobbin 253 has a circular outer diameter labeled “T_{D}”, in one example this diameter T_{D} was about 1 millimeter, but for various applications the micro-transformer 251 and bobbin 253 can be of varying dimensions. A first and second groove 252, 254 are formed on the outer surface of the bobbin 253 to be used in winding bond wire material to form the coils. The grooves have a lesser diameter labeled “T_{G}” that positions an outside surface of the grooves 252, 254 inside the outer diameter of the micro-transformer 251. When the bobbin 253 is mounted and bond wire is used to form first coil and second coil on the grooves 252, 254 (see for example wires 242, 244 in FIG. 2C and in FIG. 2DD) to form the micro-transformer 251, the two coils are positioned in the two grooves 252, 254 and are spaced apart and arranged to magnetically couple to one another when in operation. When a current flows through one coil, a corresponding current develops in the other coil, allowing the transfer of energy (or alternatively the coupling of signals) across the isolation barrier.

Bobbin 253 has a central opening with an inner surface 257 with a diameter “T_{O}”. As shown in FIGS. 2D-2E, bobbin 253, and therefore the micro-transformer formed using it (see 251 in FIG. 2DD, for example) can be a cylindrical shape with a round or circular shape in cross-section, with a hollow central opening as illustrated. Optional core 259 can be positioned in the central opening with inner surface 257 within the circumference of bobbin 253, and when used the optional core 259 will be surrounded by the coils. Other shapes can be used for bobbin 253 that allow coils to be formed around the micro-transformer, such as oval, octagon, pentagon shapes (when observed from an end or cross-sectional view), rectangular or square shapes.

FIG. 2DD shows in another side view the bobbin 253 used to form micro-transformer 251 with the bond wires 242, 244 formed into first and second coils. The grooves 252, 254 can be formed on these alternative micro-transformer shapes to support the bond wires 242, 244 wrapped around the body to form the coils. In FIG. 2DD, bobbin 253 is oriented as in FIG. 2C. The first coil is formed on groove 252 using bond wire 242. A single wrap is shown in FIGS. 2C and 2DD, but more wire wraps can be used. Bond wire 244 is shown forming the second coil in groove 254.

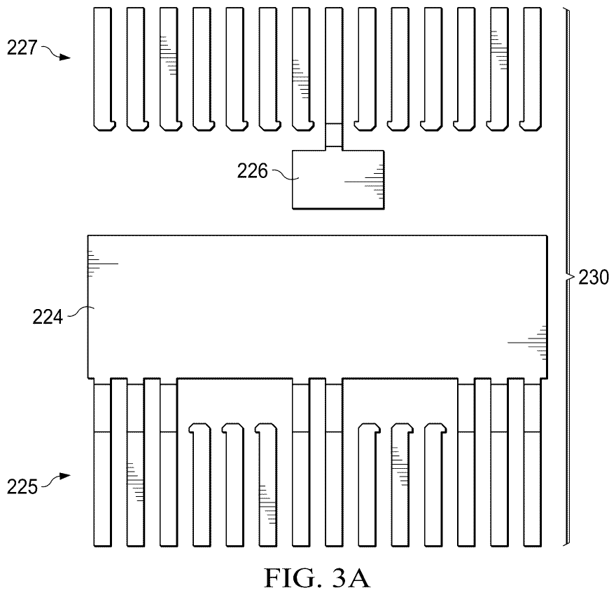

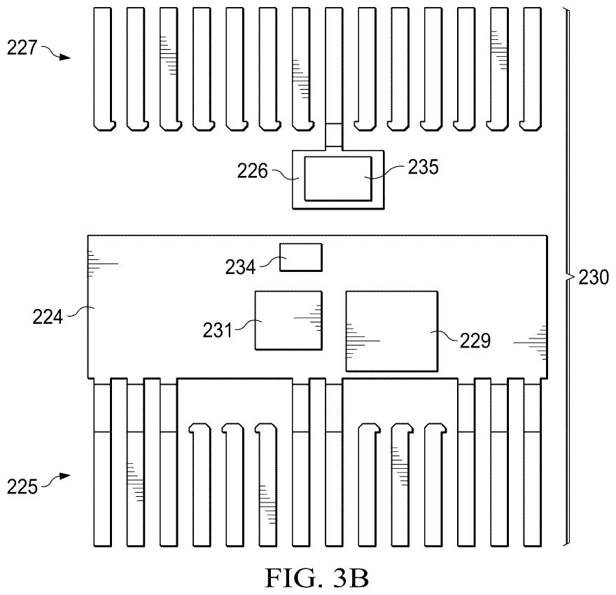

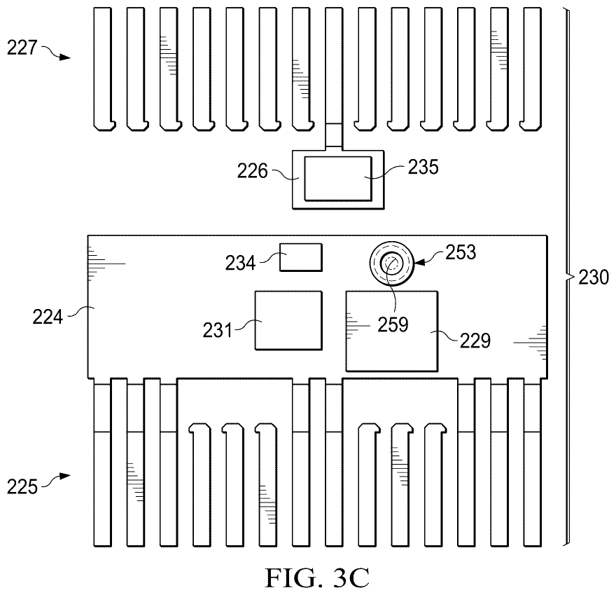

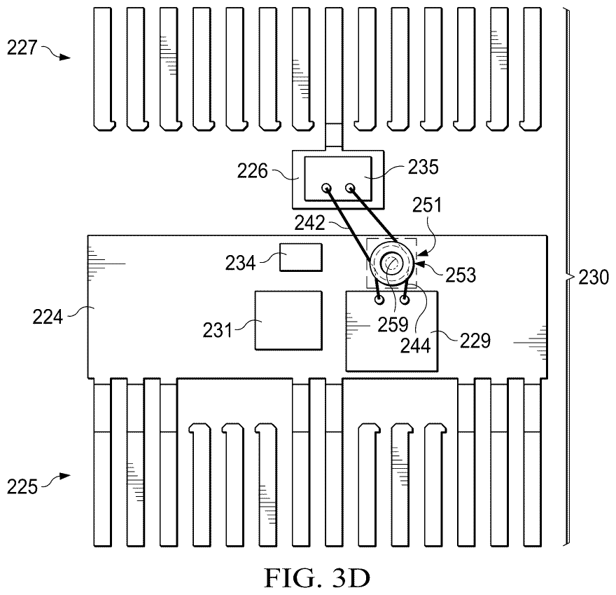

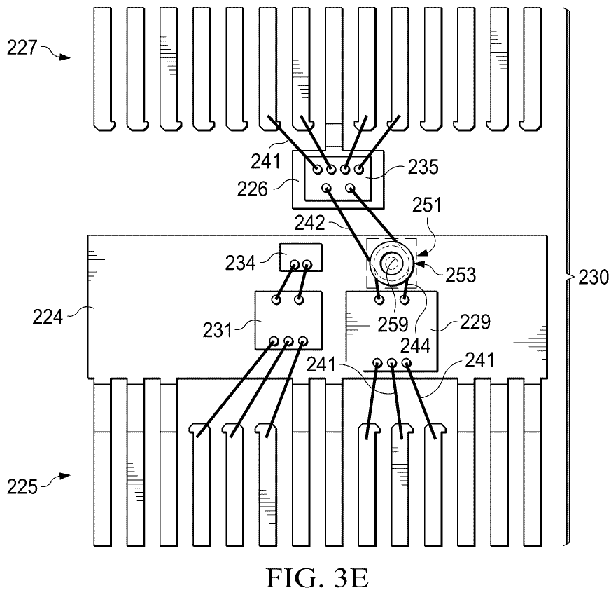

Both ends of the bond wires 242, 244 are ball bonded to bond pads on semiconductor dies (note that in the side views of FIGS. 2C, 2DD, only one end of the bond wires 242, 244 is shown, see FIG. 3D described below, where both ends of the bond wires are shown ball bonded to semiconductor dies). One form of a conventional wire bonding tool uses a “ball and stitch” bonding process, which forms a ball bond on a bond pad of a semiconductor die, and then forms a “stitch” bond on a conductive lead or conductive land by applying mechanical pressure to force the wire against the lead with heat and vibration to form a bond between like materials. Because a “stitch” bond is made without the soft molten ball of a ball bond, the mechanical stress the “stitch” puts on a conductor is greater than that for a ball bond. It is therefore not preferred to make stitch bonds to a semiconductor die bond pad, which is a thin metallic structure on a semiconductor substrate. To address this, and for die-to-die bonds in various applications, an alternative bond process uses a stand-off stitch on bump or “SSB” wire bonding process. In an example SSB process that is useful with the arrangements, an insulated bond wire for making the coils on the micro-transformer is provided as the wire supply for a wire bonding tool. The wire bonding tool has a movable capillary, which is of a hard material such as a ceramic and which has a central opening that allows the end of the wire to extend through it, and in addition the capillary or wire bonding tool has clamps that can selectively hold or release the bond wire. The capillary can move in three directions, vertically, and in two horizontal directions, and the wire bonding tool can extend the bond wire through the opening as the capillary moves, and with the clamps the capillary can pull on the bond wire to shape it.

In a process useful for forming the coils of the arrangements using SSB wire bonding, a molten ball is first formed on the exposed end of the bond wire extending through the capillary. An electronic arc or flame can be used to form the molten ball. The capillary then moves to a position over a first bond pad where one end of the coil is to be attached. A bump is formed on the first bond pad by pressing the molten ball against the first bond pad while heat and sonic energy are applied to the molten ball and the bond pad (the sonic energy can be applied as ultrasonic vibration to the capillary). As the capillary is moved from the ball bond, the bond wire is cut or broken at an edge of the ball to form a bump of bond wire material on the first bond pad.

A second molten ball is then formed on the newly exposed end of the bond wire. The capillary then moves over a second bond pad where the second end of the coil will be coupled to the semiconductor die. The ball is bonded to the second bond pad and again a thermosonic bonding process is used to bond the molten ball on the end of the bond wire to the bond pad, sonic and thermal energy are applied along with mechanical pressure from the capillary.

As the capillary moves away from the second bond pad, the bond wire extends from the ball bond through the capillary. As the capillary moves, the bond wire can be pulled on and wrapped around the bobbin. In this manner, the coil is formed. The capillary can extend and/or pull on the bond wire as needed to wrap the wire around the bobbin. Once the coil is formed around the bobbin, the capillary can move to a position over the first bond pad, where the bump was formed. Using the bond wire, the capillary can now form a stitch on the “stand-off bump,” so that the two ends of the wire that form the coil around the bobbin are both bonded to two bond pads on the semiconductor die. This process can be performed again forming the second coil around the bobbin and bonding the two ends to bond pads on the second semiconductor die. By forming the first coil on the bobbin closest to the package substrate, the second coil can be formed above the first coil using the capillary.

In an alternative arrangement (not illustrated), the grooves 252, 254 can be omitted. The number of wraps of the wires 242, 244 can be varied so that the two coils have different turns and different wire lengths, to change the current output from the current input, that is, the two coils do not have to be the same or equal. Step-up and step-down voltages can be achieved using different coil arrangements for the transformer. The wires 244, 242 can be copper, gold, aluminum or other bond wire material that are coated with an insulator. In an example arrangement, copper bond wire was used with an insulator material coating. In a particular example arrangement, a coating of aluminum oxide (Al₂O₃) was used. The insulated bond wires, when used to form coils, prevent shorting between the wraps or turns if the two parts of the wraps of a coil should come into contact with one another. In one example arrangement, an insulator coating of 10 nanometers thickness was used over 0.9-millimeter-thick bond wire. In another example, a 20-nanometer coating thickness was used over the same bond wire. Increasing the insulator coating thickness increases the dielectric breakdown voltage when wraps of the wire are in physical contact with each other.

The micro-transformer 251 can be of various sizes to fit the dimensions of the molded microelectronic device package, and package substrate, chosen for an application. The materials for the bobbin 253 of the micro-transformer can be of dielectrics useful for 3D or additive manufacturing such as PLA, ABS, nylon, polypropylene and similar materials, can be of material that can be molded such as thermoplastic materials, and can be of magnetic material such as an epoxy resin with ferrite fillers. The optional core 259 can be used or omitted in various applications, to increase the inductance obtained from the micro-transformer 251.

The wires (see 244, 242 in FIG. 2C, and in FIG. 2DD) used to form the coils can be of wires compatible with wire bonding equipment, but in contrast to bond wire used for electrical connections between devices and conductive leads, the wire can be insulated with a coating such as aluminum oxide. Using insulated bond wire for the coils prevents shorts between wraps of the coil that may be in contact with one another. The number of wraps needed is also determined by the application and the Q-factor or efficiency rating needed for the micro-transformer. The dimensions for the micro-transformer 251 are also determined by the application. In an example the micro-transformer 251 has a height extending above the package substrate of about 1 millimeter. Micro-transformer 251 is sized to be compatible with dimensions of certain standard semiconductor device packages, such as small outline packages (SOP) that have a body thickness that ranges from about 1-3.7 millimeters.

FIGS. 3A-3E illustrate, in a series of plan views, selected steps used to form a microelectronic device package of an arrangement. In the series of plan views a single unit package substrate 230 is shown to illustrate the various process steps described. However, in a production process, the package substrates can be provided as multiple units temporarily joined together in an array or grid format, with unit package substrates arranged in rows and columns, to enable gang production during the packaging processes, increasing throughput and lowering costs per unit.

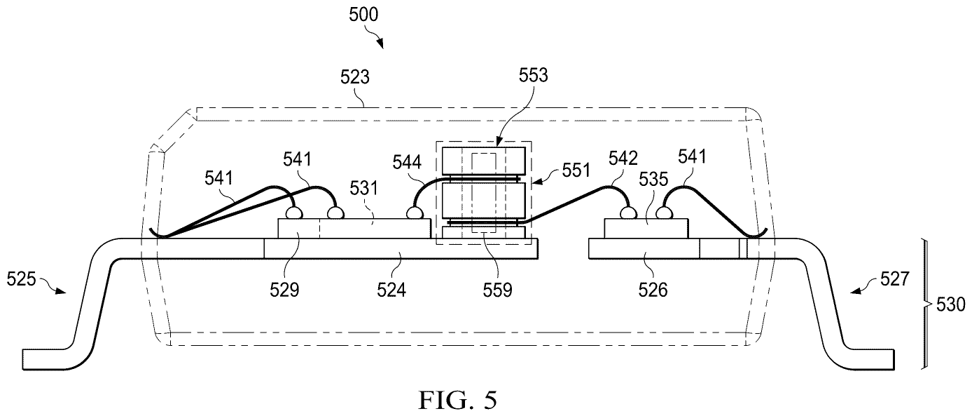

In FIG. 3A, a unit package substate 230 is shown viewed from a device side surface (note that in FIG. 3A the package substrate 230 is oriented with the device side surface facing upwards, for ease of processing, in contrast the device side surface 222 in the upset example microelectronic device package 200 of FIG. 2C is shown oriented downwards, or facing a board side of the microelectronic device package 200). The upset shape of the package substrate allows for more vertical space on the device side of the package substrate (more space when compared to a simpler planar package substrate shape, see FIG. 5 for an example). In the illustrated example of FIG. 3A, the package substrate 230 is shown implemented using a conductive leadframe. Copper, plated copper, partially plated copper, steel, and stainless-steel materials can be used, in a useful example copper or Alloy 42 can be used. The leadframe can be spot plated at locations where bond wires will be bonded to the leadframe surface, using plating materials that enhance the wire bonds, such as silver, nickel, gold, palladium, tin, and combinations of these. The leadframe can be uniformly plated over the entire surface, instead of being spot plated. The leads or portions of the leads can be plated to reduce corrosion or tarnish and to reduce or prevent ion diffusion using nickel, gold, palladium or combinations of these, such as electroless nickel immersion gold (sometimes referred to as “ENIG” plating) or electroless nickel, electroless palladium, and immersion gold (sometimes referred to as “ENEPIG” plating).

In FIG. 3A, unit package substrate 230 has a first set of leads 225 extending away from a middle portion of the leadframe, and a first die pad 224 is shown connected to the first set of leads 225. The first die pad 224 is arranged to mount at least one semiconductor die, (see FIG. 3B described below, where there are several semiconductor dies or components shown.) The first set of leads 225 and the first die pad 224 are spaced from and will be electrically isolated from the second set of leads 227 and the second die pad 226, which can be used to mount at least one or several components including semiconductor dies and passive components. The first set of leads 225 and the first die pad 224 are arranged to be coupled to a first voltage domain with a first ground, and the second set of leads 227 and the second die pad 226 are arranged to be coupled to a second voltage domain with a second ground that is isolated from the first ground. Because the first ground and the second ground are electrically isolated from each other, voltages can occur between the first set of leads and the second set of leads in tens, hundreds or even thousands of volts, so that for the microelectronics device package to be reliable and have a useful lifetime, robust electrical isolation is needed between the first set of leads 225 and the second set of leads 227, and between components mounted on the first die pad 224 and those components mounted to the second die pad 226. Use of the arrangements enables robust electrical isolation.

FIG. 3B illustrates, in another plan view from the device side surface, the package substrate 230 after components 229, 231, 234, and 235 are mounted on the first die pad 224 and on the second die pad 226 using a die mounting process. The components can include semiconductor dies and passive components, for example. In an example application, which can include components arranged as part of a power device, at least one of the semiconductor dies can be a switching power device, in one example a gallium nitride field effect transistor (GaN FET) commercially available from Texas Instruments, Incorporated of Dallas, Texas, USA can be used. The GaN FET semiconductor device includes a power transistor with a low on-resistance drain-to-source current path arranged to deliver current from a voltage to a load. In the illustrated examples, semiconductor die 231 can be a primary side controller device that is coupled to the power FET device 229, while the semiconductor die 234 can be an isolation die that uses a dielectric between two conductors to form a signal isolation device. The semiconductor die 235 can be a second side controller device, which is isolated from the other dies in the package.

In FIG. 3B, the devices 229, 231, and 234 are shown mounted on the die pad 224 using, for example, a die attach film, die attach epoxy, or die attach paste. In an example a conductive die attach film (CDAF) can be used, alternatively a non-conductive die attach film (NCDAF) can be used. Ink jet printed or drop-on-demand die attach materials can be used. Another semiconductor die 235 is shown mounted on the second die pad 226, which is spaced from and will be electrically isolated from the first die pad 224. Again, conductive, or non-conductive die attach film, die attach epoxy or paste can be used to mount the semiconductor die 235.

In a particular example arrangement, semiconductor die 229 can be a power switching device that will carry current to a load from a supply voltage. In additional example arrangements, other circuitry can be implemented by mounting various components on the package substrate 230, for example an AC-DC converter or a DC-DC converter can be provided.

FIG. 3C illustrates, in a further plan view, the elements of FIG. 3B after a bobbin 253 for forming a micro-transformer is mounted. The bobbin 253 can be mounted using epoxy, die attach adhesive, silver, or another adhesive. Bobbin 253 is an insulator and is electrically isolated from both die pad 224 and die pad 226.

In FIG. 3D, the elements of FIG. 3C are shown after the coils are formed. A first wire bonder operation is used to form the coils around bobbin 253. Wire 242 is connected by wire bonding operations to bond pads on semiconductor die 235 on the die pad 226. Wire 244 is connected by wire bonding to semiconductor die 229 on die pad 224. Wire 242 can be used to form a coil by using a wire bonding tool and wrapping the wire around bobbin 253 in a first groove. Wire 244 can be used to form a second coil by using the wire bonding tool and wrapping the wire around bobbin 253 in a second groove on the bobbin 253. In a useful process, an automated wire bonder tool can be used to form the coils using wires 242, 244. To form the coils, a capillary is moved around the bobbin 253 and the wire is pulled while the capillary moves around the bobbin 253 to wrap the wire around the bobbin 253, each of the two ends of the bond wires 242, 244 are bonded to conductive bond pads on the corresponding semiconductor die that is to be coupled to the wires. The bobbin 253 and the wires 242, 244 form a micro-transformer 251. An optional core 259 is shown positioned in a central opening of bobbin 253.

In FIG. 3E, the elements of FIG. 3D are shown after a second wire bonding operation makes electrical connections by forming wire bonds between the semiconductor dies 229, 231, 234 and 235, and other components, and between the semiconductor dies 229, 235 and other components and conductive leads of the package substrate 230. In a wire bonding operation useful with the arrangements, electrical connections are formed using bond wire coupled between bond pads on semiconductor dies or other components, and conductive leads of the package substrate, such as leads of the leadframe. In an example process, automated wire bonding equipment can rapidly make hundreds of bond wire connections in succession, and in a production mode, can move from unit device to unit device on a grid or array of unit devices, completing the necessary wire bonds very quickly. The second wire bonding process can use a ball and stitch bonding process, as the second connection of each wire bond is to a conductive lead instead of to a bond pad of a semiconductor die. However, other wire bonding processes can also be used in forming the arrangements.

In FIG. 3E, wire bonds 241 are shown connecting the semiconductor dies 229, 231, 234, and 235 (or other components) to the leads of the package substrate 230, as well as to one another. The first set of leads 225 have wire bonds 241 connecting to the semiconductor dies and components 229, 231, and 234. The second set of leads 227 have wire bonds 241 connecting to the semiconductor die 235.

In an example ball bonding process that can be used with the arrangements, a wire bonding tool includes a hard capillary of ceramic or another insulator that has a central opening. A supply of bond wire is arranged so that the end of the bond wire extends from a central opening in the capillary. A wire bonding cycle begins by forming a molten ball on the end of the bond wire extending from the capillary, in example processes this can be done using a flame or by using an electronic arc to melt the exposed end of the bond wire, forming the molten ball. The capillary is then positioned to push the molten ball onto a bond pad. In the automated wire bonding tool, mechanical pressure, heat, and ultrasonic vibration can be applied to perform thermosonic wire bonding, to attach the molten ball to the bond pad. The capillary then moves away from the ball bond on the bond pad while allowing the bond wire to extend through the capillary and from the ball bond, and the capillary is then positioned over a conductive portion of a lead of the package substrate, or over another bond pad on another device. Again, using mechanical pressure and ultrasonic energy, a stitch bond is formed on the lead, and as the capillary moves a short distance away from the stitch bond, the extending bond wire is cut or broken to leave a free end of the bond wire extending from the capillary. The free end of the bond wire is ready for another cycle. This process is referred to as “ball and stitch” wire bonding.

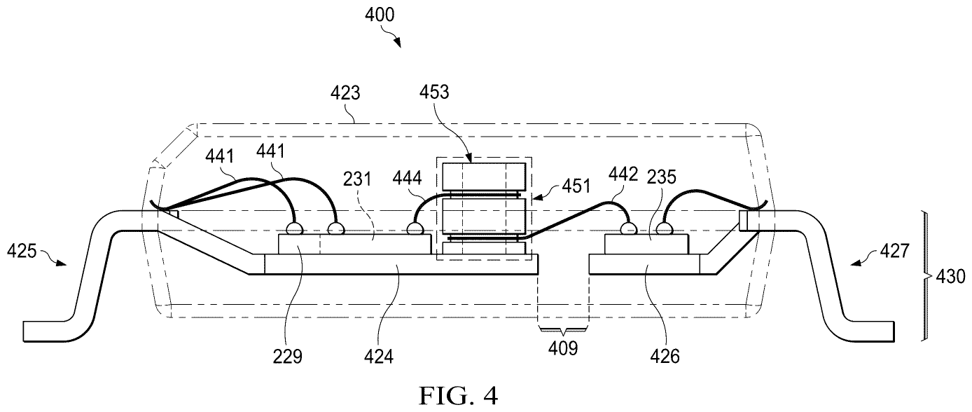

FIG. 4. illustrates, in a cross-sectional view, an alternative arrangement for a microelectronic device package 400. In FIG. 4, a micro-transformer 451 is mounted on a “downset” type package substrate 430. Micro-transformer 451 can be similar to micro-transformer 251 in FIG. 2C and in FIG. 2DD, for example. The leads 425, 427 of the package substrate, for example a conductive leadframe, are arranged in a downset” configuration so that the die pads 424, 426 that are arranged for mounting the components 229, 231 and 235 lie in a plane that is closer to a board side of the body of the microelectronic device package 400 formed by mold compound 423 (closer than to the middle portion of the microelectronic device package 400, where leads 425, 427 enter the package body.) The spacing between the die pads 424, 426 form an electrical isolation barrier, numbered 409, between the elements. The leads 425, 427 are shown with “gull wing” shapes to enable mounting to a board or module using solder in a surface mount technology (SMT) process. The components 229, 231, and 235 can be the same as those used in the arrangement of FIG. 2C, however in this alternative arrangement a different package substrate 430 is used to arrange the elements, which are now positioned facing away from the board side surface (in contrast to the illustrated example arrangement of FIG. 2C where the components face the board side surface of the package 200 formed using an upset type of leadframe.)

In FIG. 4, wires 442, 444 form two coils around bobbin 453 to form micro-transformer 451, with the wire 442 coupled by ball bonds to bond pads of the semiconductor die 235, and the wire 444 coupled by ball bonds to bond pads on the semiconductor die 231. The downset leadframe of package substrate 430 provides additional vertical space above the leadframe for the micro-transformer 451 without increasing the thickness of the microelectronic device package 400 (over a standard package thickness.)

FIG. 5 illustrates, in a further cross-sectional view, an additional alternative arrangement for a microelectronic device package 500. In FIG. 5, the package substrate 530 has die pads 524, 526 in an arrangement using a planar leadframe, that is neither an upset or downset type leadframe, instead the leads 525 and 527 and the die pads 524, 526 lie in the same plane. In FIG. 5, mold compound 523 forms a package body around the semiconductor dies 535, 529 that are mounted on the die pads 524, 526. Bobbin 553 of a micro-transformer 551, which can be similar to micro-transformer 451 or 251 described above, is also mounted on die pad 524. Wires 542, 544 form coils around the bobbin 553 and are coupled to the semiconductor die 529 and to the semiconductor die 535. The example illustrated also shows an optional ferrite core 559 positioned in a central opening in bobbin 553 of micro-transformer 551. Wire bonds 541 further couple the semiconductor dies 535, 529 to leads 525, 527 of the package substrate 530.

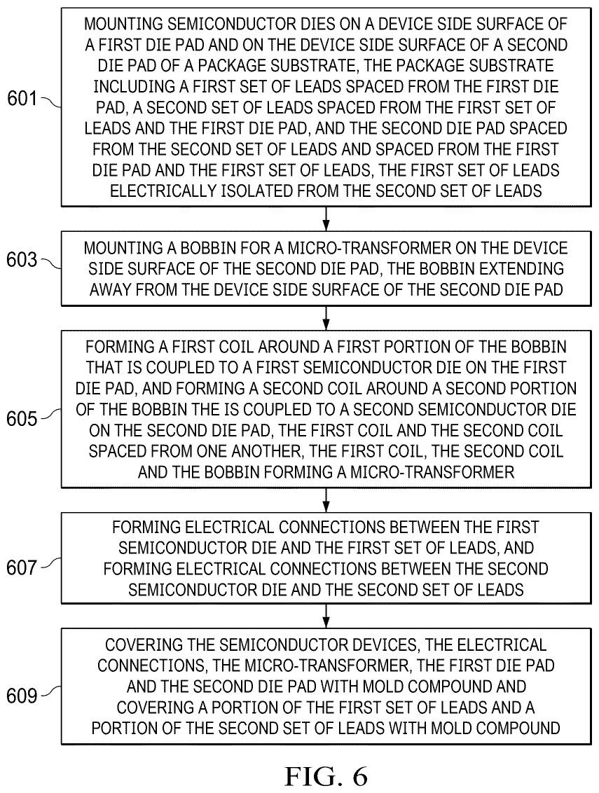

FIG. 6 illustrates, in a flow diagram, the steps used to form a microelectronic device package using the micro-transformer in an example arrangement.

The method begins at step 601, by mounting semiconductor devices on a device side surface of a package substrate on a first die pad and on the device side surface of a second die pad of the package substrate, the package substrate further comprising a first set of leads spaced from the first die pad, a second set of leads spaced from the first set of leads and the first die pad, and the second die pad spaced from the second set of leads and spaced from the first die pad and the first set of leads, the first set of leads electrically isolated from the second set of leads. (See, for example, the package substrate 230 in FIG. 3B, with first die pad 224 and second die pad 226, and semiconductor dies 229 and 235).

At step 603, the method continues by mounting a bobbin for a micro-transformer on the device side surface of the second die pad, the bobbin extending away from the device side surface of the second die pad. (See, for example, FIG. 3C, where bobbin 253 is mounted to die pad 224).

At step 605, the method continues by forming a first coil around a first portion of the bobbin that is coupled to a first semiconductor die on the first die pad, and forming a second coil around a second portion of the bobbin that is coupled to a second semiconductor die on the second die pad, the first coil and the second coil spaced from one another, the first coil, the second coil and the bobbin forming a micro-transformer (See, for example, wire 242 and wire 244 in FIG. 3D, forming a first coil and a second coil around the bobbin 253 in micro-transformer 251, see also the details of the bobbin 253 in FIGS. 2D, 2DD-2E and the descriptions above). Wire bonding tools with movable capillaries can be used to wrap the bond wire around the bobbin to form the first and second coils, and to bond the ends of the coils to the bond pads of the corresponding semiconductor dies.

At step 607, the method continues by forming electrical connections between bond pads on the semiconductor dies and the first set of leads and the second set of leads. (See, for example, FIG. 3E, and wire bonds 241).

At step 609, the method is completed by covering the semiconductor devices, the electrical connections, the micro-transformer, the first die pad and the second die pad with mold compound and covering a portion of the first set of leads and a portion of the second set of leads with mold compound. (See, for example, FIG. 2C, where mold compound 223 is shown covering the elements). The mold compound 223 is cured and forms the body of the microelectronic device package (see, for example, microelectronic device package 200 in FIGS. 2C, 400 in FIG. 4, or 500 in FIG. 5, and the corresponding descriptions above).

The use of the arrangements and methods provide microelectronic device packages including semiconductor dies that are isolated from one another by an isolation barrier to provide robust isolation, with an integral micro-transformer used to couple components across the isolation barrier. Existing materials and assembly tools are used to form the arrangements, and the arrangements are relatively low in cost. Using wire bonding tools already in use to form the micro-transformers by coiling wire around a bobbin mounted on a die pad contemporaneously with die packaging processes allows for cost savings (over the use of expensive laminate transformers that require expensive tooling to produce.) The bobbin can be manufactured using economical 3D printing or additive manufacturing. The use of the arrangements allows microelectronic device packages including isolation barriers with an integrated transformer at low cost (when compared to prior approaches such as using laminate transformers), and using existing tools such as wire bonders already used for packaging the semiconductor devices.

Modifications are possible in the described arrangements, and other alternative arrangements are possible within the scope of the claims.

What is claimed is:

1. An apparatus, comprising:
a package substrate having a device side surface and comprising a first set of leads spaced from a first die pad configured for mounting semiconductor dies, and having a second set of leads spaced from a second die pad configured for mounting additional semiconductor dies, the first die spaced from the second die pad, a space between the first die pad and the second die pad forming an electrical isolation barrier;
at least one semiconductor die mounted to the device side surface of the first die pad and at least one semiconductor die mounted to the device side surface of the second die pad;
a bobbin mounted on the device side surface of the second die pad, the bobbin extending away from the device side surface of the second die pad;
a first coil around a first portion of the bobbin and coupled to a first semiconductor die on the first die pad, and a second coil around a second portion of the bobbin coupled to a second semiconductor die on the second die pad, the first coil and the second coil spaced from one another, the first coil, the second coil and the bobbin forming a micro-transformer;
electrical connections formed between bond pads of at least one semiconductor die on the first die pad and the first set of leads, and formed between bond pads of the at least one semiconductor die on the second die pad and the second set of leads; and
mold compound covering the first die pad, the second die pad, the electrical connections, the micro-transformer, portions of the first set of leads, and portions of the second set of leads, the mold compound forming a body of a microelectronic device package.

2. The apparatus of claim 1, wherein the bobbin comprises polylactic acid (“PLA”), acetonitrile butadiene styrene (“ABS”), acrylonitrile styrene acrylate (“ASA”), nylon, or polypropylene.

3. The apparatus of claim 1, wherein the microelectronic device package is a small outline package (SOP) with a body width of less than 8 millimeters.

4. The apparatus of claim 1, wherein the bobbin comprises a ferrite material.

5. The apparatus of claim 1, wherein the bobbin has a circular outer diameter and has a central opening.

6. The apparatus of claim 5 and further comprising a ferrite core disposed in the central opening.

7. The apparatus of claim 1, wherein the first coil and the second coil comprise insulated bond wire wrapped around the bobbin.

8. The apparatus of claim 7, wherein the first coil is disposed in a first groove at the first portion of the bobbin, and the second coil is disposed in a second groove at the second portion of the bobbin.

9. The apparatus of claim 1, wherein the electrical connections comprise wire bonds of a bond wire that comprises copper, copper alloy, palladium coated copper, aluminum, silver, or gold.

10. A microelectronic device package, comprising:
a package substrate having a device side surface and an opposite side surface and comprising a first set of leads spaced from a first die pad configured for mounting semiconductor dies, and having a second set of leads spaced from a second die pad configured for mounting additional semiconductor dies, the first die pad and the first set of leads spaced from the second die pad and the second set of leads forming an electrical isolation barrier;
at least one semiconductor die mounted to the device side surface of the first die pad and at least one semiconductor die mounted to the device side surface of the second die pad;
a bobbin mounted on the device side surface of the second die pad, the bobbin extending away from the device side surface of the second die pad;
a first coil of insulated bond wire wrapped around a first groove in a first portion of the bobbin and coupled to a first semiconductor die on the first die pad, and a second coil of the insulated bond wire wrapped around a second groove in a second portion of the bobbin coupled to a second semiconductor die on the second die pad, the first coil and the second coil spaced from one another, the first coil, the second coil and the bobbin forming a micro-transformer;
wire bonds between bond pads of the at least one semiconductor die on the first die pad and the first set of leads, and between bond pads of the at least one semiconductor die on the second die pad and the second set of leads; and
mold compound covering the first die pad, the second die pad, the electrical connections, the micro-transformer, portions of the first set of leads, and portions of the second set of leads.

11. The microelectronic device package of claim 10, wherein the bobbin comprises one of comprises polylactic acid (“PLA”), acetonitrile butadiene styrene (“ABS”), acrylonitrile styrene acrylate (“ASA”), nylon, or polypropylene.

12. The microelectronic device package of claim 10, wherein the bobbin comprises ferrite material.

13. A method, comprising:
mounting semiconductor dies on a device side surface of a package substrate on a first die pad and on the device side surface of a second die pad of the package substrate, the package substrate further comprising a first set of leads spaced from the first die pad, a second set of leads spaced from the first set of leads and the first die pad, and the second die pad spaced from the second set of leads and spaced from the first die pad and the first set of leads, the first set of leads electrically isolated from the second set of leads;
mounting a bobbin on the device side surface of the second die pad, the bobbin extending away from the device side surface of the second die pad;
forming a first coil around a first portion of the bobbin that is coupled to a first semiconductor die on the first die pad, and forming a second coil around a second portion of the bobbin that is coupled to a second semiconductor die on the second die pad, the first coil and the second coil spaced from one another, the first coil, the second coil and the bobbin forming a micro-transformer;
forming electrical connections between bond pads on the semiconductor dies and the first set of leads and the second set of leads; and
covering the semiconductor dies, the electrical connections, the first die pad and the second die pad, and the micro-transformer with mold compound, and covering a portion of the first set of leads and a portion of the second set of leads with the mold compound, the mold compound forming a body of a microelectronic device package.

14. The method of claim 13, wherein mounting the bobbin comprises mounting the bobbin that comprises polylactic acid (“PLA”), acetonitrile butadiene styrene (“ABS”), acrylonitrile styrene acrylate (“ASA”), nylon, or polypropylene.

15. The method of claim 13, wherein the bobbin has a circular outer diameter and a central opening and further comprising disposing a ferrite core in the central opening.

16. The method of claim 13, wherein the bobbin comprises a ferrite material.

17. The method of claim 13, wherein forming the first coil further comprises extending an insulated bond wire from a first bond pad on the first semiconductor die and around the first portion of the bobbin and ending the insulated bond wire on a second bond pad on the first semiconductor die.

18. The method of claim 13, wherein forming the second coil further comprises extending an insulated bond wire from a first bond pad on the second semiconductor die and around the second portion of the bobbin and ending the insulated bond wire on a second bond pad on the second semiconductor die.

19. The method of claim 13, wherein forming electrical connections further comprises forming wire bonds between the first semiconductor die and the first set of leads and forming wire bonds between the second semiconductor die and the second set of leads.

20. The method of claim 13 wherein the microelectronic device package is a small outline package (SOP) with a lead-to-lead pitch of less than 1 millimeter.

21. The method of claim 13, wherein forming electrical connections further comprises wire bonding to form wire bond connections between bond pads on the semiconductor dies mounted on the first die pad and the first set of leads.

22. The method of claim 13, wherein the package substrate further comprises a conductive leadframe with a space between the first die pad and the second die pad forming an electrical isolation barrier.
